(19) United States
(12) Patent Application Publication
(10) Pub. No.: US 2025/0318196 A1
(43) Pub. Date: Oct. 9, 2025

(54) THIN-FILM TRANSISTOR DEVICE AND PREPARATION METHOD THEREOF, AND DISPLAY PANEL

(71) Applicant: Shenzhen China Star Optoelectronics Semiconductor Display Technology Co., Ltd., Shenzhen (CN)

(72) Inventor: Nian LIU, Shenzhen (CN)

(73) Assignee: Shenzhen China Star Optoelectronics Semiconductor Display Technology Co., Ltd., Shenzhen (CN)

(21) Appl. No.: 18/991,681

(22) Filed: Dec. 22, 2024

(30) Foreign Application Priority Data
Apr. 7, 2024 (CN) 202410405595.2

(51) Int. Cl. H10D 30/67; H10D 30/01; H10D 64/23; H10D 64/66; H10D 64/68; H10D 86/40

(52) U.S. Cl. CPC H10D 30/6737; H10D 30/0318; H10D 30/6728; H10D 64/252; H10D 64/668; H10D 64/669; H10D 64/691; H10D 86/451

(57) ABSTRACT

In a thin-film transistor device, an inorganic insulating layer covers the via wall of a via, an active layer is disposed on a first electrode, the inorganic insulating layer, and a second electrode, a gate insulating layer covers the active layer, and a gate is disposed on a side of the gate insulating layer away from the via wall of the via, where the first electrode, the second electrode, and the inorganic insulating layer have the same conductive element.

### CROSS-REFERENCE TO RELATED APPLICATION

This disclosure claims priority to Chinese Patent Application No. 202410405595.2, filed with the China National Intellectual Property Administration (CNIPA) on Apr. 7, 2024, the contents of which are incorporated herein by reference.

### TECHNICAL FIELD

The present disclosure relates to the field of display technology, for example, a thin-film transistor device and a preparation method thereof, and a display panel.

### BACKGROUND

Thin-film transistor devices in the high refresh rate, low energy consumption, and demultiplexing drive products need to have a large on-state current to meet the demand for charging rate, or the dimension of thin-film transistor devices may be reduced to achieve a narrow bezel and high penetration rate. The short channel technology may be adopted to significantly improve the on-state current of the devices and reduce the dimension of the devices; if the channel is narrowed down to 1 micron, the on-state current, compared to the conventional thin-film transistor devices, can be increased by more than 4 times.

Vertical channels can dramatically reduce the dimension of the channels and increase the current throughput capacity per unit area of thin-film transistor devices. However, the insulating layers are etched to open the holes, which will cause damage to the back channel surface, such as uneven morphology and a large number of broken bonds, resulting in electrical degradation.

### SUMMARY

Embodiments of the present disclosure provide a thin-film transistor device and a preparation method thereof, and a display panel.

Embodiments of the present disclosure provide a thin-film transistor device.

The thin-film transistor device includes a substrate, a first electrode, an interlayer dielectric layer, a second electrode, an inorganic insulating layer, an active layer, a gate insulating layer, and a gate.

The first electrode is disposed on the substrate.

The interlayer dielectric layer covers the first electrode and the substrate, where a via is provided in the interlayer dielectric layer, and the via exposes the first electrode.

The second electrode is disposed on a side of the interlayer dielectric layer away from the substrate.

The inorganic insulating layer covers a via wall of the via.

The active layer is disposed on the first electrode, the inorganic insulating layer, and the second electrode. The active layer is connected to the first electrode and the second electrode.

The gate insulating layer covers the active layer.

The gate is disposed on a side of the gate insulating layer away from the via wall of the via.

The first electrode, the second electrode, and the inorganic insulating layer have the same conductive element.

Correspondingly, embodiments of the present disclosure further provide a preparation method of a thin-film transistor device, including the following.

A first substrate electrode, an interlayer dielectric layer, and a second substrate electrode are formed sequentially on a substrate.

The interlayer dielectric layer is patterned to form a via, where the via exposes at least a portion of the first substrate electrode.

A conductive material layer is formed on the interlayer dielectric layer, where the conductive material layer includes a first part, a second part, and a third part which are sequentially connected, the first part covers the second substrate electrode, the second part covers the sidewall of the via, and the third part covers the exposed portion of the first substrate electrode.

The conductive material layer is oxidized or nitrided at a temperature no less than 300 degrees Celsius to cause the third part and the first substrate electrode to be converted into a first electrode, cause the second part to be converted into an inorganic insulating layer, and cause the first part and the second substrate electrode to be converted into a second electrode.

An active layer, a gate insulating layer, and a gate are formed sequentially on the inorganic insulating layer, the active layer is connected to the first electrode and the second electrode, and the gate is disposed on a side of the gate insulating layer away from the via wall of the via.

Correspondingly, embodiments of the present disclosure further provide a display panel, including the thin-film transistor device as described in any of the above embodiments.

### BRIEF DESCRIPTION OF THE DRAWINGS

FIG. 1 is a diagram showing the structure of a thin-film transistor device provided by some embodiments of the present disclosure.

FIG. 2 is a top view of a thin-film transistor device provided by some embodiments of the present disclosure.

FIG. 3 is a diagram showing the structure of another thin-film transistor device provided by some embodiments of the present disclosure.

FIG. 4 is a diagram showing the structure of yet another thin-film transistor device provided by some embodiments of the present disclosure.

FIG. 5 is a schematic diagram of a structure prepared after step B1 of a preparation method of a thin-film transistor device provided by some embodiments of the present disclosure.

FIG. 6 is a schematic diagram of a structure prepared after step B2 of a preparation method of a thin-film transistor device provided by some embodiments of the present disclosure.

FIG. 7 is a schematic diagram of a structure prepared after step B3 of a preparation method of a thin-film transistor device provided by some embodiments of the present disclosure.

FIG. 8 is a schematic diagram of a structure prepared after step B4 of a preparation method of a thin-film transistor device provided by some embodiments of the present disclosure.

FIG. 9 is a schematic diagram of a structure prepared after step B5 of a preparation method of a thin-film transistor device provided by some embodiments of the present disclosure.

### DETAILED DESCRIPTION

In the present disclosure, unless specified to the contrary, the used orientation words such as “up” and “down” usually refer to up and down in the actual use or working state of the device, specifically the drawing directions in the accompanying drawings, and “inside” and “outside” are with respect to the contour of the device. The terms “first”, “second”, “third”, etc., are used only as labels and are not regarded as numerical requirements or establish an order.

Embodiments of the present disclosure provide a thin-film transistor device and a preparation method thereof, and a display panel, as described in detail below. It is to be noted that the order in which the following embodiments are described does not serve as the preferred order of the embodiments.

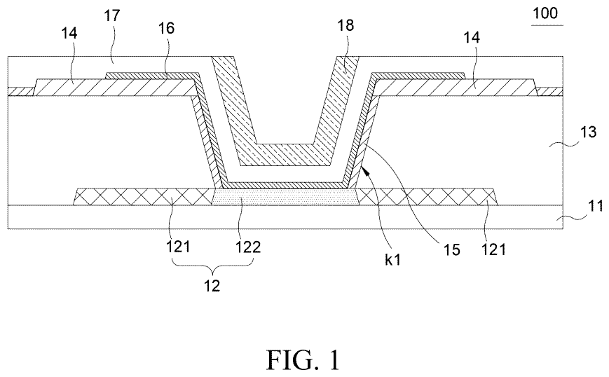

Referring to FIG. 1, embodiments of the present disclosure provide a thin-film transistor device 100 including a substrate 11, a first electrode 12, an interlayer dielectric layer 13, a second electrode 14, an inorganic insulating layer 15, an active layer 16, a gate insulating layer 17, and a gate 18.

The first electrode 12 is provided on the substrate 11. The interlayer dielectric layer 13 covers the first electrode 12 and the substrate 11. A via k1 is provided in the interlayer dielectric layer 13, and the via k1 exposes the first electrode 12. The second electrode 14 is provided on a side of the interlayer dielectric layer 13 away from the substrate 11. The inorganic insulating layer 15 covers the via wall of the via k1. The active layer 16 is provided on the first electrode 12, the inorganic insulating layer 15, and the second electrode 14. The active layer 16 is connected to the first electrode 12 and the second electrode 14. The gate insulating layer 17 covers the active layer 16. The gate 18 is provided on a side of the gate insulating layer 17 away from the via wall of the via k1. The first electrode 12, the second electrode 14 and the inorganic insulating layer 15 all have the same conductive element.

In the thin-film transistor device 100 of the embodiments of the present disclosure, the inorganic insulating layer 15 covers the via wall of the via k1 to compensate for damage to the via wall of the via k1 due to etching, and provides a good back channel film surface for the formation of the active layer 16, thereby improving the performance of the thin-film transistor device 100. Furthermore, the first electrode 12, the second electrode 14, and the inorganic insulating layer 15 all have the same conductive element, which enables the inorganic insulating layer 15, at least a portion of the first electrode 12, and at least a portion of the second electrode 14 to be formed at one time by high-temperature oxidization or nitridation of the same material, thereby saving the photomask process.

Optionally, in some embodiments of the present disclosure, the flatness of the surface of the inorganic insulating layer 15 contacting the active layer 16 is superior to the flatness of the via wall of the via k1. The inorganic insulating layer 15 provides a flat back channel film surface for the active layer 16, reducing the risk of unevenness of the back channel of the active layer 16, and the inorganic insulating layer 15 prevents the active layer 16 from being affected by a large number of broken bonds in the via wall, thereby further improving the performance of the active layer 16.

Optionally, in some embodiments of the present disclosure, the refractive index of the inorganic insulating layer 15 is greater than the refractive index of the interlayer dielectric layer 13. It is to be understood that the denser (higher density of) the film layer is, the higher the refractive index is, i.e., the denseness of the inorganic insulating layer 15 is higher than the denseness of the interlayer dielectric layer 13, which reduces defects on the back channel film surface, and thus improves the performance of the thin-film transistor device 100.

Optionally, one of the first electrode 12 and the second electrode 14 is a source, and the other of the first electrode 12 and the second electrode 14 is a drain.

Optionally, the substrate 11 may be a rigid substrate or a flexible substrate. The material of the substrate 11 includes one of glass, sapphire, silicon, silicon dioxide, polyethylene, polypropylene, polystyrene, polylactic acid, polyethylene dimethacrylate, polyethylene glycol adipate, polyethylene terephthalate, polyethylene naphthalate, polycarbonate, polyethersulfone, aromatic fluoro-toluene containing a polyarylate, polycyclic olefins, polyimides or polyurethane.

Optionally, the material of the interlayer dielectric layer 13 may be formed as a bi-layer formed by stacking inorganic layers including at least one of silicon oxide, silicon nitride, silicon nitride oxide, aluminum oxide, magnesium oxide or titanium oxide; alternatively, the material of the interlayer dielectric layer 13 may be formed as a multi-layer formed by alternately stacking inorganic layers including at least one of silicon oxide, silicon nitride, silicon nitride oxide, aluminum oxide, magnesium oxide or titanium oxide. However, the present disclosure is not limited thereto, and the interlayer dielectric layer 13 may be formed as a single inorganic layer including the insulating material described above.

Further, in one or more embodiments, the interlayer dielectric layer 13 may be made of an organic insulating material such as polyimide (PI).

Optionally, the material of the active layer 16 includes monocrystalline silicon, polycrystalline silicon or an oxide semiconductor.

Optionally, the second electrode 14 is disposed on at least one side of the via k1. For example, the second electrode 14 is disposed on a single side of the via k1; or the second electrode 14 is disposed on opposing sides of the via k1; or the second electrode 14 is provided to extend around the circumference of the via k1.

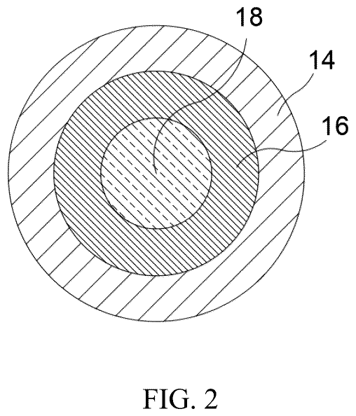

Referring to FIG. 2, an example is shown where the second electrode 14 is provided to extend around the circumference of the via k1. The second electrode 14 is in an annulus shape, and the gate 18 is provided within the via k1 and extends around the circumference of the via k1. A portion of the active layer 16 is provided within the via k1, another portion of the active layer 16 is lapped onto the second electrode 14, and the active layer 16 is provided extending around the circumference of the via k1.

In an embodiment, the inorganic insulating layer 15 further covers the side of the interlayer dielectric layer 13 away from the substrate 11 to improve water resistance.

Optionally, the gate insulating layer 17 further covers the second electrode 14.

In an embodiment, the conductive element includes a silicon element and an aluminum element. The conductive element may also be a magnesium element and a titanium element.

Optionally, in an embodiment of the present disclosure, at least a portion of the first electrode 12 is a metal silicide, at least a portion of the second electrode 14 is a metal silicide, and the inorganic insulating layer 15 is a silicide.

For example, at least a portion of the first electrode 12 is a metal silicon oxide, at least a portion of the second electrode 14 is a metal silicon oxide, and the inorganic insulating layer 15 is a silicon oxide; alternatively, at least a portion of the first electrode 12 is a metal silicon nitride, at least a portion of the second electrode 14 is a metal silicon nitride, and the inorganic insulating layer 15 is a silicon nitride; alternatively, at least a portion of the first electrode 12 is a metal silicon oxynitride, at least a portion of the second electrode 14 is metal silicon oxynitride, and the inorganic insulating layer 15 is silicon oxynitride.

It is noted that both the first electrode 12 and the second electrode 14 have electrical conductivity and can properly realize the function of the thin-film transistor device 100.

In some embodiments of the present disclosure, at least a portion of the first electrode 12 is an aluminum alloy, at least a portion of the second electrode 14 is an aluminum alloy, and the inorganic insulating layer 15 is an aluminum oxide; alternatively, at least a portion of the first electrode 12 is a titanium alloy, at least a portion of the second electrode 14 is a titanium alloy, and the inorganic insulating layer 15 is titanium oxide.

In an embodiment, one side of the inorganic insulating layer 15 is connected to the first electrode 12, and the other side of the inorganic insulating layer 15 is connected to the second electrode 14.

At least a portion of the first electrode 12 is a metal silicide, at least a portion of the second electrode 14 is a metal silicide, and the inorganic insulating layer 15 is a silicide. Alternatively, at least a portion of the first electrode 2 is an aluminum alloy, at least a portion of the second electrode 14 is an aluminum alloy, and the inorganic insulating layer 15 is an aluminum oxide.

The at least portion of the first electrode 12, the inorganic insulating layer 15, and the at least portion of the second electrode 14 are formed at the same time, i.e., the same process is used to form the at least portion of the first electrode 12, the inorganic insulating layer 15, and the at least portion of the second electrode 14, to achieve a process-saving effect.

Optionally, in an embodiment of the present disclosure, the first electrode 12 includes a first portion 121 and a second portion 122 which are connected, the first portion 121 being covered by the interlayer dielectric layer 13, and the second portion 122 being connected to the active layer 16. The first portion 121 has a resistance value smaller than the resistance value of the second portion 122. One side of the inorganic insulating layer 15 is connected to the second electrode 14, and the other side of the inorganic insulating layer 15 is connected to the second portion 122. The second portion 122 is a metal silicide, the second electrode 14 is a metal silicide, and the inorganic insulating layer 15 is a silicide; alternatively, the second portion 122 is an aluminum alloy, the second electrode 14 is an aluminum alloy, and the inorganic insulating layer 15 is an aluminum oxide; alternatively, the second portion 122 is a titanium alloy, the second electrode 14 is a titanium alloy, and the inorganic insulating layer 15 is a titanium oxide.

That is, the first portion 121 is a single layer of metal material, and the material of both the second portion 122 and the second electrode 14 is one of a metal silicide, an aluminum alloy or a titanium alloy.

Optionally, the metal silicide or the aluminum alloy includes at least one of nickel, copper or titanium. The first portion 121 includes at least one of nickel, copper or titanium.

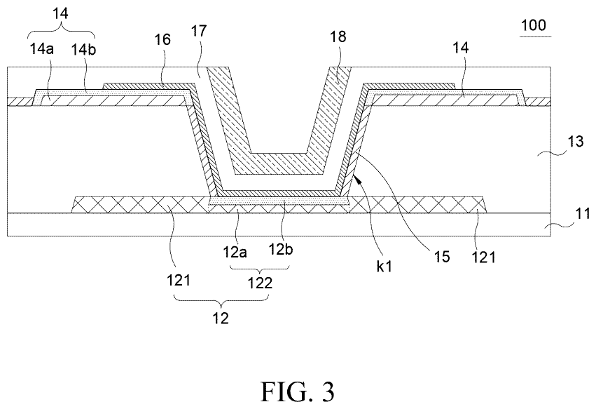

Referring to FIG. 3, the difference in an embodiment of the present disclosure, compared to the above embodiments, is as follows.

The first electrode 12 includes a first portion 121 and a second portion 122 which are connected, a side of the first portion 121 away from the substrate 11 is covered with the interlayer dielectric layer 13, and the second portion 122 is connected to the active layer 16. The first portion 121 is a single layer of metal material, and the second portion 122 includes a first metal layer 12a and a first conductive layer 12b disposed on a side of the first metal layer 12a away from the substrate 11. The first portion 121 and the first metal layer 12a are of the same material.

The first conductive layer 12b is a metal silicide and the inorganic insulating layer 15 is a silicide; alternatively, the first conductive layer 12b is an aluminum alloy and the inorganic insulating layer 15 is an aluminum oxide; alternatively, the first conductive layer 12b is a titanium alloy and the inorganic insulating layer 15 is a titanium oxide.

The thickness of the first portion 121 is greater than the thickness of the first metal layer 12a.

Optionally, the material of the first portion 121 and the first metal layer 12a includes at least one of nickel, copper or titanium.

Optionally, the material of the first conductive layer 12b is one of a metal silicide, an aluminum alloy or a titanium alloy. The first conductive layer 12b has the same metal particles as the first metal layer 12a. For example, when the first metal layer 12a is a copper layer, the material of the first conductive layer 12b is one of a copper silicide, an aluminum-copper alloy or a titanium-copper alloy.

The second electrode 14 includes a second metal layer 14a and a second conductive layer 14b provided on a side of the second metal layer 14a away from the substrate 11.

The second conductive layer 14b is a metal silicide and the inorganic insulating layer 15 is a silicide; alternatively, the second conductive layer 14b is an aluminum alloy and the inorganic insulating layer 15 is an aluminum oxide; alternatively, the second conductive layer 14b is a titanium alloy and the inorganic insulating layer 15 is a titanium oxide.

Optionally, the material of the second metal layer 14a includes at least one of nickel, copper or titanium.

Optionally, the material of the second conductive layer 14b is one of a metal silicide, an aluminum alloy or a titanium alloy. The second conductive layer 14b has the same metal particles as the second metal layer 14a. For example, when the second metal layer 14a is a copper layer, the material of the second conductive layer 14b is one of a copper silicide, an aluminum-copper alloy or a titanium-copper alloy.

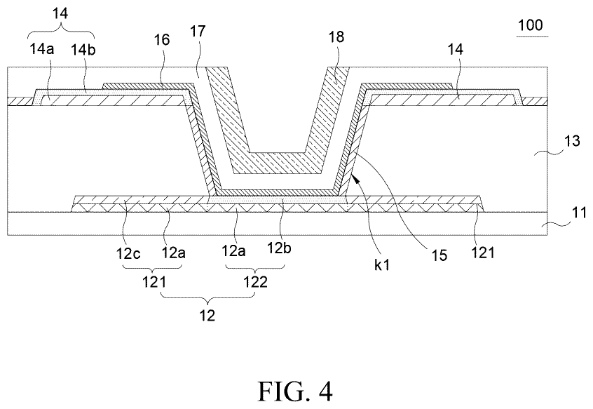

Referring to FIG. 4, the difference in an embodiment of the present disclosure, compared to the above embodiments, is as follows.

The first electrode 12 includes a first portion 121 and a second portion 122 which are connected, a side of the first portion 121 away from the substrate 11 is covered with the interlayer dielectric layer 13, and the second portion 122 is connected to the active layer 16. The second portion 122 includes a first metal layer 12a and a first conductive layer 12b disposed on a side of the first metal layer 12a away from the substrate 11. The first portion 121 includes the first metal layer 12a and a third metal layer 12c disposed on the side of the first metal layer 12a away from the substrate 11.

The first conductive layer 12b is a metal silicide and the inorganic insulating layer 15 is a silicide; alternatively, the first conductive layer 12b is an aluminum alloy and the inorganic insulating layer 15 is an aluminum oxide; alternatively, the first conductive layer 12b is a titanium alloy and the inorganic insulating layer 15 is a titanium oxide.

Optionally, the first metal layer 12a and the third metal layer 12c are of different materials.

The material of the first conductive layer 12b is one of a metal silicide, an aluminum alloy or a titanium alloy. The first conductive layer 12b has the same metal particles as the third metal layer 12c. For example, when the third metal layer 12c is a titanium layer, the material of the first conductive layer 12b is one of a titanium silicide or a titanium-aluminum alloy.

Optionally, the material of the second conductive layer 14b is one of a metal silicide, an aluminum alloy or a titanium alloy. The second conductive layer 14b has different metal particles than the second metal layer 14a. For example, when the second metal layer 14a is a titanium layer, the material of the second conductive layer 14b is one of a copper silicide or a copper-aluminum alloy.

Accordingly, embodiments of the present disclosure also provide a preparation method of a thin-film transistor device, including the following.

A first substrate electrode s1, an interlayer dielectric layer 13, and a second substrate electrode s2 are sequentially formed on a substrate 11.

The interlayer dielectric layer 13 is patterned to form a via k1, and the via k1 exposes at least a portion of the first substrate electrode s1.

A conductive material layer dd is formed on the interlayer dielectric layer 13, and the conductive material layer dd includes a first part d1, a second part d2, and a third part d3 sequentially connected. The first part d1 covers the second substrate electrode s2, the second part d2 covers the sidewall of the via k1, and the third part d3 covers the exposed portion of the first substrate electrode s1.

The conductive material layer dd is oxidized or nitrided at a temperature no less than 300 degrees Celsius to cause the third part d3 and the first substrate electrode s1 to be converted into a first electrode 12, cause the second part d2 to be converted into an inorganic insulating layer 15, and cause the first part d1 and the second substrate electrode s2 to be converted into a second electrode 14.

An active layer 16, a gate insulating layer 17, and a gate 18 are sequentially formed on the inorganic insulating layer 15, the active layer 16 is connected to the first electrode 12 and the second electrode 14, and the gate 18 is disposed on a side of the gate insulating layer 17 away from the via wall of the via k1.

It should be noted that the preparation method of the thin-film transistor device in the embodiments is used to prepare the thin-film transistor device 100 in the above embodiments. The preparation method of the thin-film transistor device is described below.

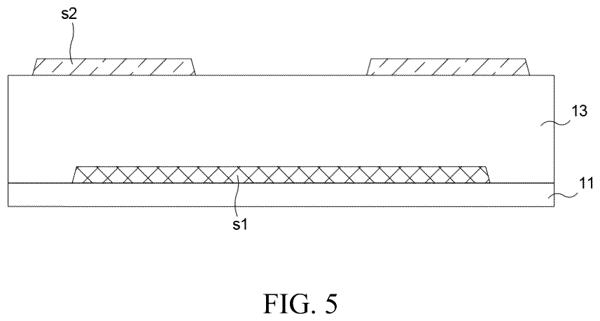

Referring to FIG. 5, at step B1, a first substrate electrode s1, an interlayer dielectric layer 13, and a second substrate electrode s2 are sequentially formed on a substrate 11.

A patterned first substrate electrode s1 is first formed on the substrate 11, the material of the first substrate electrode s1 being metal. Subsequently, the interlayer dielectric layer 13 is formed. Then a patterned second substrate electrode s2 is formed on the interlayer dielectric layer 13, the material of the second substrate electrode s2 being metal.

Subsequently, move to step B2.

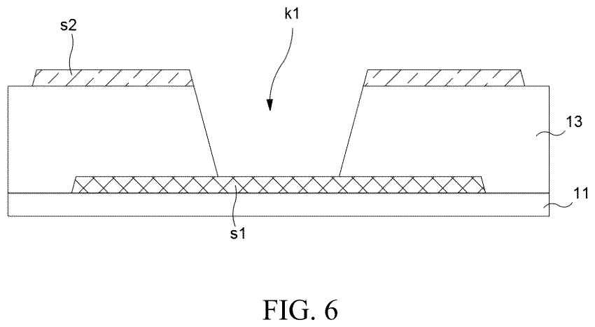

Referring to FIG. 6, at step B2, the interlayer dielectric layer 13 is patterned to form a via k1, the via k1 exposing at least a portion of the first substrate electrode s1.

Optionally, the interlayer dielectric layer 13 is etched using wet etching or dry etching to form the via k1. The via k1 exposes a portion of the first substrate electrode s1.

Subsequently, move to step B3.

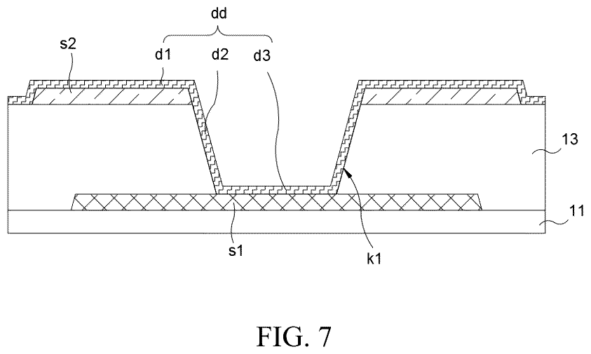

Referring to FIG. 7, at step B3, a conductive material layer dd is formed on the interlayer dielectric layer 13, the conductive material layer dd including a first part d1, a second part d2, and a third part d3 sequentially connected. The first part d1 covers the second substrate electrode s2, the second part d2 covers the sidewall of the via k1, and the third part d3 covers the exposed portion of the first substrate electrode s1.

Optionally, the conductive material layer dd may be made of silicon, aluminum, titanium or hydrogenated amorphous silicon.

Optionally, the conductive material layer dd has a thickness between 5 nm and 50 nm.

It is to be understood that if the conductive material layer dd is too thick, the oxidation or nitridation reaction at the bottom of the conductive material layer dd is incomplete within a set time, and the conductive material layer dd still has semiconductor or conductor characteristics, leading to abnormal device characteristics; if the conductive material layer dd is too thin, it will lead to uneven film thickness. Therefore, to ensure that the function of the thin-film transistor device is normal while improving the uniformity of the film thickness, the thickness of the conductive material layer dd may be 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm or 50 nm, etc.

Subsequently, move to step B4.

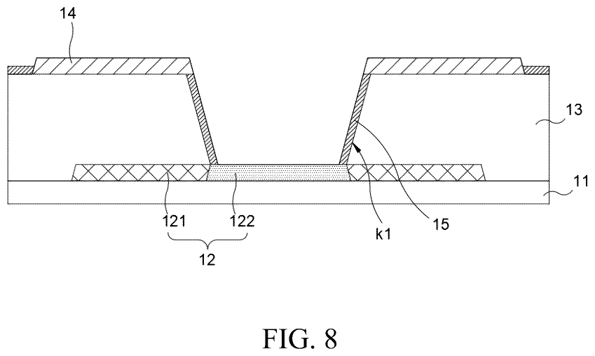

Referring to FIG. 8, at step B4, the conductive material layer dd is oxidized or nitrided at a temperature no less than 300 degrees Celsius to cause the third part d3 and the first substrate electrode s1 to be converted into a second portion 122 of a first electrode 12, cause the second part d2 to be converted into an inorganic insulating layer 15, and cause the first part d1 and the second substrate electrode s2 to be converted into a second electrode 14.

At a high-temperature environment no less than 300 degrees Celsius, the metal particles in the first part d1 and the third part d3 can diffuse into the conductive material layer dd to form the first electrode 12 and the second electrode 14 having a metal silicide, a metal aluminum alloy or a metal titanium alloy.

When high-temperature oxidation is performed, the first electrode 12 and the second electrode 14 each have one of a metal silicon oxide, an aluminum alloy or a titanium alloy, and the second part d2 is converted to a silicon oxide.

When high-temperature nitriding is performed, the first electrode 12 and the second electrode 14 each have metal silicon nitride, and the second part d2 is converted to a silicon nitride.

It should be noted that when the first substrate electrode s1 is relatively thick (the embodiment corresponding to FIG. 3), the metal of the top portion of the first substrate electrode s1 diffuses into the third part d3; when the first substrate electrode s1 is relatively thin (the embodiment corresponding to FIG. 1), all of the metal of the first substrate electrode s1 diffuses into the third part d3; and when the first substrate electrode s1 is a multi-layered stacked metal structure, the top metal layer of the structure diffuses into the third part d3. When the second substrate electrode s2 is relatively thick (the embodiment corresponding to FIG. 3), the metal of the top portion of the second substrate electrode s2 will diffuse into the first part d1; when the second substrate electrode s2 is relatively thin (the embodiment corresponding to FIG. 1), all of the metal of the second substrate electrode s2 will diffuse into the first part d1; and when the second substrate electrode s2 is a multi-layered stacked metal structure, the top metal layer of the structure diffuses into the first part d1.

The inorganic insulating layer 15, the first electrode 12, and the second electrode 14 are formed sequentially using high-temperature oxidation or nitridation to achieve a process-saving effect.

Subsequently, move to step B5.

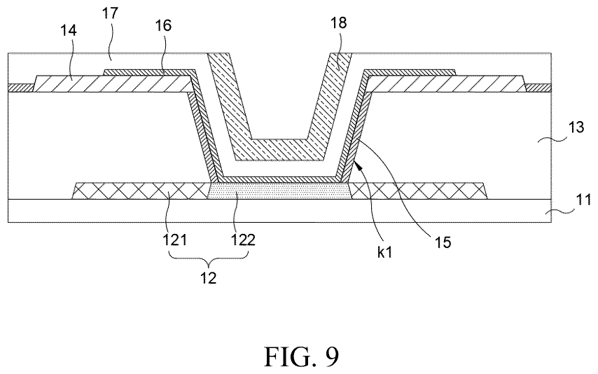

Referring to FIG. 9, at step B5, an active layer 16, a gate insulating layer 17, and a gate 18 are formed sequentially on the inorganic insulating layer 15, the active layer 16 is connected to the first electrode 12 and the second electrode 14, and the gate 18 is provided on a side of the gate insulating layer 17 away from the via wall of the via k1.

Optionally, the gate 18 may be formed using a metal element selected from chromium, copper, aluminum, gold, silver, zinc, molybdenum, tantalum, titanium, tungsten, manganese, nickel, iron and cobalt, or an alloy having any of the foregoing metal elements as a constituent thereof, or a combination of the alloy having any of the foregoing metal elements. In addition, the gate may have a single-layered structure or a structure with two or more stacked layers.

In this manner, the preparation method of the thin-film transistor device in the embodiments of the present disclosure is achieved.

Accordingly, embodiments of the present disclosure also provide a display panel including the thin-film transistor device as described in any of the above embodiments.

It should be noted that the structure of the thin-film transistor device in the display panel of the embodiment of the present disclosure is similar to or the same as the structure of the thin-film transistor device 100 of the above-described embodiments, and therefore will not be repeated herein.

Optionally, the display panel may be a liquid crystal display panel or an electroluminescent panel.

The thin-film transistor device of the display panel in the embodiments of the present disclosure includes the substrate, the first electrode, the interlayer dielectric layer, the second electrode, the inorganic insulating layer, the active layer, the gate insulating layer, and the gate. The first electrode is disposed on the substrate. The interlayer dielectric layer covers the first electrode and the substrate. The via is provided in the interlayer dielectric layer, and the via exposes at least a portion of the first electrode. The second electrode is disposed on the side of the interlayer dielectric layer away from the substrate. The inorganic insulating layer covers the via wall of the via. The active layer is provided on the first electrode, the inorganic insulating layer, and the second electrode, and the active layer is connected to the first electrode and the second electrode. The gate insulating layer covers the active layer. The gate is provided on the side of the gate insulating layer away from the via wall of the via. The first electrode, the second electrode, and the inorganic insulating layer have the same conductive element.

In the embodiments of the present disclosure, the inorganic insulating layer covers the via wall of the via to compensate for damage to the via wall of the via due to etching, and provides a good back channel film surface for the formation of the active layer, thereby improving the performance of the thin-film transistor device. Furthermore, the first electrode, the second electrode, and the inorganic insulating layer all have the same conductive element, which enables the inorganic insulating layer, at least a portion of the first electrode, and at least a portion of the second electrode to be formed at one time by high-temperature oxidization or nitridation of the same material, thereby saving the photomask process.

What is claimed is:

1. A thin-film transistor device, comprising:
a substrate;
a first electrode disposed on the substrate;
an interlayer dielectric layer covering the first electrode and the substrate, wherein a via is provided in the interlayer dielectric layer, and the via exposes the first electrode;
a second electrode disposed on a side of the interlayer dielectric layer away from the substrate;
an inorganic insulating layer covering a via wall of the via;
an active layer disposed on the first electrode, the inorganic insulating layer, and the second electrode, the active layer being connected to the first electrode and the second electrode;
a gate insulating layer covering the active layer; and
a gate disposed on a side of the gate insulating layer away from the via wall of the via;
wherein the first electrode, the second electrode, and the inorganic insulating layer have a same conductive element.

2. The thin-film transistor device according to claim 1, wherein the conductive element comprises a silicon element or an aluminium element.

3. The thin-film transistor device according to claim 2, wherein one side of the inorganic insulating layer is connected to the first electrode, and the other side of the inorganic insulating layer is connected to the second electrode; and
at least a portion of the first electrode is a metal silicide, at least a portion of the second electrode is a metal silicide, and the inorganic insulating layer is a silicide; or, at least a portion of the first electrode is an aluminum alloy, at least a portion of the second electrode is an aluminum alloy, and the inorganic insulating layer is an aluminum oxide.

4. The thin-film transistor device according to claim 3, wherein the first electrode comprises a first portion and a second portion which are connected;
a side of the first portion away from the substrate is covered by the interlayer dielectric layer, the second portion is connected to the active layer, and the first portion has a resistance value smaller than a resistance value of the second portion;
the one side of the inorganic insulating layer is connected to the second portion; and
the second portion is the metal silicide, the second electrode is the metal silicide, and the inorganic insulating layer is the silicide; or, the second portion is the aluminum alloy, the second electrode is the aluminum alloy, and the inorganic insulating layer is the aluminum oxide.

5. The thin-film transistor device according to claim 3, wherein the second electrode comprises a second metal layer and a second conductive layer provided on a side of the second metal layer away from the substrate; and
the second conductive layer is the metal silicide, and the inorganic insulating layer is the silicide; or, the second conductive layer is the aluminum alloy, and the inorganic insulating layer is the aluminum oxide.

6. The thin-film transistor device according to claim 5, wherein the first electrode comprises a first portion and a second portion which are connected;
a side of the first portion away from the substrate is covered by the interlayer dielectric layer, and the second portion is connected to the active layer;
the first portion is a single layer of metal material, the second portion comprises a first metal layer and a first conductive layer disposed on a side of the first metal layer away from the substrate, and the first portion and the first metal layer are of a same material; and
the first conductive layer is the metal silicide, and the inorganic insulating layer is the silicide; or, the first conductive layer is the aluminum alloy, and the inorganic insulating layer is the aluminum oxide.

7. The thin-film transistor device according to claim 5, wherein the first electrode comprises a first portion and a second portion which are connected;
a side of the first portion away from the substrate is covered by the interlayer dielectric layer, and the second portion is connected to the active layer;
the second portion comprises a first metal layer and a first conductive layer disposed on a side of the first metal layer away from the substrate, and the first portion comprises the first metal layer and a third metal layer disposed on the side of the first metal layer away from the substrate; and
the first conductive layer is the metal silicide, and the inorganic insulating layer is the silicide; or, the first conductive layer is the aluminum alloy, and the inorganic insulating layer is the aluminum oxide.

8. The thin-film transistor device according to claim 3, wherein the metal silicide or the aluminum alloy comprises at least one of nickel, copper or titanium.

9. The thin-film transistor device according to claim 1, wherein a flatness of a surface of the inorganic insulating layer contacting the active layer is superior to a flatness of the via wall of the via.

10. A preparation method of a thin-film transistor device, comprising:
sequentially forming a first substrate electrode, an interlayer dielectric layer, and a second substrate electrode on a substrate;
patterning the interlayer dielectric layer to form a via, wherein the via exposes at least a portion of the first substrate electrode;
forming a conductive material layer on the interlayer dielectric layer, wherein the conductive material layer comprises a first part, a second part, and a third part which are sequentially connected, the first part covers the second substrate electrode, the second part covers a sidewall of the via, and the third part covers the exposed portion of the first substrate electrode;
oxidizing or nitriding the conductive material layer at a temperature no less than 300 degrees Celsius to cause the third part and the first substrate electrode to be converted into a first electrode, cause the second part to be converted into an inorganic insulating layer, and cause the first part and the second substrate electrode to be converted into a second electrode; and
sequentially forming an active layer, a gate insulating layer, and a gate on the inorganic insulating layer, wherein the active layer is connected to the first electrode and the second electrode, and the gate is disposed on a side of the gate insulating layer away from a via wall of the via.

11. The preparation method of the thin-film transistor device according to claim 10, wherein the conductive material layer has a thickness between 5 nm and 50 nm.

12. A display panel, comprising one or more thin-film transistor devices;
wherein each of the thin-film transistor devices comprises:
a substrate;
a first electrode disposed on the substrate;
an interlayer dielectric layer covering the first electrode and the substrate, wherein a via is provided in the interlayer dielectric layer, and the via exposes the first electrode;
a second electrode disposed on a side of the interlayer dielectric layer away from the substrate;
an inorganic insulating layer covering a via wall of the via;
an active layer disposed on the first electrode, the inorganic insulating layer, and the second electrode, the active layer being connected to the first electrode and the second electrode;
a gate insulating layer covering the active layer; and
a gate disposed on a side of the gate insulating layer away from the via wall of the via;
wherein the first electrode, the second electrode, and the inorganic insulating layer have a same conductive element.

13. The display panel according to claim 12, wherein the conductive element comprises a silicon element or an aluminium element.

14. The display panel according to claim 13, wherein one side of the inorganic insulating layer is connected to the first electrode, and the other side of the inorganic insulating layer is connected to the second electrode; and
at least a portion of the first electrode is a metal silicide, at least a portion of the second electrode is a metal silicide, and the inorganic insulating layer is a silicide; or, at least a portion of the first electrode is an aluminum alloy, at least a portion of the second electrode is an aluminum alloy, and the inorganic insulating layer is an aluminum oxide.

15. The display panel according to claim 14, wherein the first electrode comprises a first portion and a second portion which are connected;
a side of the first portion away from the substrate is covered by the interlayer dielectric layer, the second portion is connected to the active layer, and the first portion has a resistance value smaller than a resistance value of the second portion;
the one side of the inorganic insulating layer is connected to the second portion; and
the second portion is the metal silicide, the second electrode is the metal silicide, and the inorganic insulating layer is the silicide; or, the second portion is the aluminum alloy, the second electrode is the aluminum alloy, and the inorganic insulating layer is the aluminum oxide.

16. The display panel according to claim 14, wherein the second electrode comprises a second metal layer and a second conductive layer provided on a side of the second metal layer away from the substrate; and
the second conductive layer is the metal silicide, and the inorganic insulating layer is the silicide; or, the second conductive layer is the aluminum alloy, and the inorganic insulating layer is the aluminum oxide.

17. The display panel according to claim 16, wherein the first electrode comprises a first portion and a second portion which are connected;
a side of the first portion away from the substrate is covered by the interlayer dielectric layer, and the second portion is connected to the active layer;
the first portion is a single layer of metal material, the second portion comprises a first metal layer and a first conductive layer disposed on a side of the first metal layer away from the substrate, and the first portion and the first metal layer are of a same material; and
the first conductive layer is the metal silicide, and the inorganic insulating layer is the silicide; or, the first conductive layer is the aluminum alloy, and the inorganic insulating layer is the aluminum oxide.

18. The display panel according to claim 16, wherein the first electrode comprises a first portion and a second portion which are connected;
a side of the first portion away from the substrate is covered by the interlayer dielectric layer, and the second portion is connected to the active layer;
the second portion comprises a first metal layer and a first conductive layer disposed on a side of the first metal layer away from the substrate, and the first portion comprises the first metal layer and a third metal layer disposed on the side of the first metal layer away from the substrate; and
the first conductive layer is the metal silicide, and the inorganic insulating layer is the silicide; or, the first conductive layer is the aluminum alloy, and the inorganic insulating layer is the aluminum oxide.

19. The display panel according to claim 14, wherein the metal silicide or the aluminum alloy comprises at least one of nickel, copper or titanium.

20. The display panel according to claim 12, wherein a flatness of a surface of the inorganic insulating layer contacting the active layer is superior to a flatness of the via wall of the via.
